(19) United States
(12) Patent Application Publication
(10) Pub. No.: US 2025/0220990 A1
(43) Pub. Date: Jul. 3, 2025

(54) GATE CUT PLUG WITH THIN HERMETIC LINER AND LOW-K FILL FOR REDUCED CAPACITANCE AND OXIDATION

(71) Applicant: Intel Corporation, Santa Clara, CA (US)

(72) Inventors: Swapnadip Ghosh, Hillsboro, OR (US); Yulia Gotlib, Hillsboro, OR (US); Hanbyeol Jeong, Hillsboro, OR (US); Matthew Prince, Portland, OR (US); Andrew Arnold, Hillsboro, OR (US); Sachin Vaidya, Portland, OR (US); Ryan Pearce, Beaverton, OR (US); Chiao-Ti Huang, Portland, OR (US); Robert Mitchell, Portland, OR (US); Rajaram Pai, Lake Oswego, OR (US)

(73) Assignee: Intel Corporation, Santa Clara, CA (US)

(21) Appl. No.: 18/400,578

(22) Filed: Dec. 29, 2023

(51) Int. Cl. H01L 29/06; H01L 21/8234; H01L 23/48; H01L 23/528; H01L 23/532; H01L 27/088; H01L 29/423; H01L 29/786

(52) U.S. Cl. CPC H10D 62/118; H01L 23/481; H01L 23/5286; H01L 23/5329; H10D 30/6735; H10D 30/6757; H10D 62/115; H10D 84/0149; H10D 84/0151; H10D 84/038; H10D 84/83

(57) ABSTRACT

Integrated circuit (IC) device isolation structures between transistor gates. An IC device may include an electrically insulating structure between metal gates of adjacent transistors, and the insulating structure may include a dielectric liner around a different dielectric fill material and on sidewalls of the adjacent metal gates. The dielectric liner may be much thinner than the dielectric fill material. A metal via may be through, and in contact with, the dielectric fill material. The adjacent transistors and metal gates may be between frontside and backside interconnect structures, and the metal via may extend between, and couple, the interconnect structures.

### BACKGROUND

Especially as integrated circuit (IC) devices are further miniaturized, adjacent transistor gates may be separated by small thicknesses of dielectric materials, for example, in metal gate cut plugs. Use in such structures of dielectric materials with high relative permittivities (or high dielectric constants, i.e., “high-K” dielectric materials), e.g., silicon nitride, results in high capacitance between adjacent gates, which impairs overall device performance. While low permittivity (or “low-K”) materials might otherwise be desired, low-K materials (such as silicon oxide) often contain higher proportions of oxygen, and deposition of oxygen-containing materials on gate metal results in metal oxidation. Such oxidation may cause undesired shifts in, and unpredictable variation of, threshold voltage (e.g., related to gate endcap materials and structures).

New structures, techniques, and materials are needed to improve device performance and reduce process variation.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1 illustrates a cross-sectional profile view of an integrated circuit (IC) device having adjacent nonplanar transistors with gate structures separated by isolation structures, in accordance with some embodiments;

FIG. 2 illustrates a cross-sectional profile view of an IC device having adjacent nonplanar transistors with gate structures separated by isolation structures, in accordance with some embodiments;

FIG. 3 illustrates a cross-sectional profile view of an IC device having adjacent nonplanar transistors with gate structures separated by various isolation structures, in accordance with some embodiments;

FIG. 4 illustrates a cross-sectional profile view of an IC device having isolation structures between adjacent transistors and vias, in accordance with some embodiments;

FIGS. 5A, 5B, and 5C illustrate plan views of an IC device having isolation structures between adjacent transistors and vias, in accordance with some embodiments;

FIG. 6 is a flow chart of methods for forming an IC device with dielectric isolation structures between and separating transistor gate structures, in accordance with some embodiments;

FIG. 7 illustrates a diagram of an example data server machine employing an IC device having gate plugs with barrier layers around bulk low-K dielectric materials, in accordance with some embodiments; and

FIG. 8 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve the performance of integrated circuit (IC) devices with dielectric structures adjacent transistor gates, for example, metal gate cut plugs.

Adjacent electrically conductive structures may have significant parasitic capacitances between the structures, especially when dimensions separating the adjacent structures are very small. Such parasitic capacitances may limit operating speeds, but may be reduced by deploying electrically insulating materials with lower permittivities. While isolating adjacent transistors with low-permittivity (“low-K”) dielectrics may be desired, e.g., to increase operating speeds, low-K dielectrics may have higher oxygen content that, when deposited on gate work-function metals, may result in undesired and unpredictable shifts in transistor threshold voltages. Dielectrics with lower oxygen content may have undesirably high permittivities. The present disclosure describes low-K isolation structures between transistor gates and adjacent structures with (e.g., thin, hermetic) layers on a gate, for example to prevent gate oxidation. Structures adjacent transistor gates may include other transistor gates. In many embodiments, the bulk of the isolation structure includes oxygen. In some such embodiments, the bulk of the isolation structure includes another element, such as silicon. In many embodiments, the isolation structure includes or is enclosed in a thin, hermetic liner layer, e.g., around a low-K oxide and on the transistor gate. In some embodiments, the liner layer includes nitrogen. In some such embodiments, the liner layer includes another element, such as silicon.

The isolation structures may be metal gate cut plugs between metal transistor gates. The isolation structure may be between a transistor gate and an adjacent metal structure, such as a via. Such a via may be between interconnect layers over and under the transistor. In some embodiments, the transistor is in a device layer between front- and back-side interconnect layers, and the via couples to both the front- and back-side interconnect layers. An adjacent via may extend through the isolation structure, with portions of the isolation structure on both sides of the via, between the via and one or more adjacent transistors.

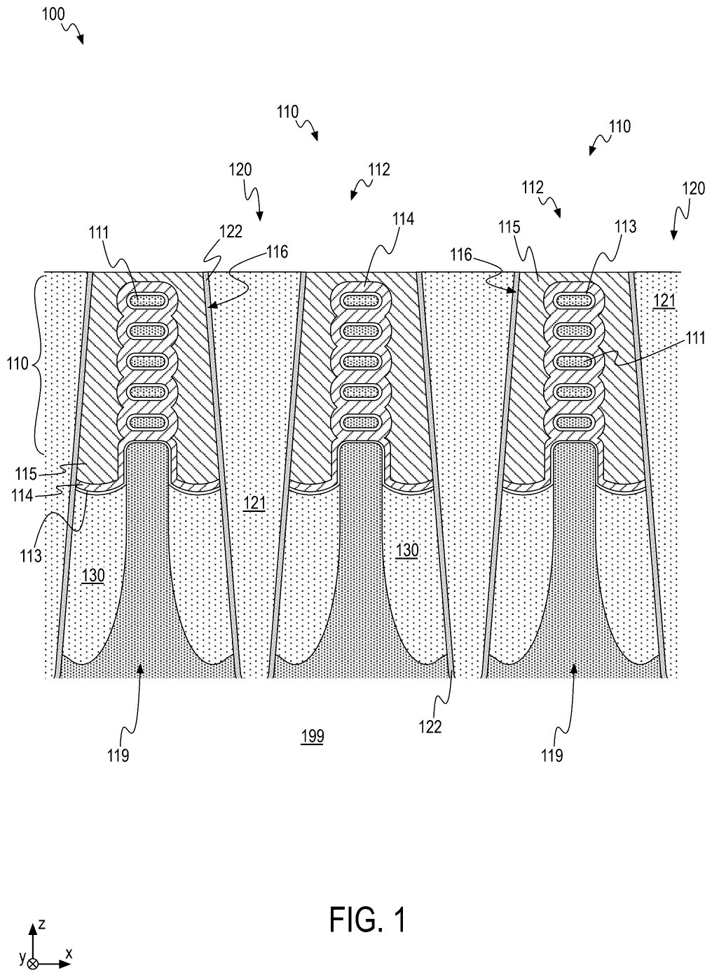

FIG. 1 illustrates a cross-sectional profile view of an IC device 100 having adjacent nonplanar transistors 110 with gate structures 112 separated by isolation structures 120, in accordance with some embodiments. The nonplanar transistors 110 shown include gate structure 112 over channel region 111. In the exemplary embodiments of FIG. 1, transistors 110 are gate all around (GAA) field-effect transistors (FET), and channel regions 111 are in stacks of nanoribbons (extending in both y-directions, through the viewing plane). Stacks of nanoribbon channel regions 111 are over fins 119 of substrate 199 in device 100. Isolation 130 (e.g., shallow trench isolation (STI)) is between fins 119. Isolation structures 120 extend downward between transistors 110 and gate structures 112, through STI 130 between fins 119, and into a material of substrate 199 below fins 119.

Gate structures 112 include gate dielectric 113 (on, over, and surrounding channel regions 111), and gate metals 114, 115, as well as gate sidewalls 116. Device 100 includes isolation structure 120 between adjacent transistors 110. Intervening layers 122 are between adjacent gate sidewalls 116 (of transistors 110 and gate structures 112) and a dielectric material 121 of isolation structure 120. Intervening layers 122 are on (e.g., in direct contact with) adjacent gate sidewalls 116. Isolation structure 120 includes, or is between, intervening layers 122. Dielectric material 121 of isolation structure 120 is separated from each adjacent transistor 110 (e.g., sidewall 116) by, and in contact with, a corresponding layer 122.

Isolation structure 120 is an electrically insulating structure, such as a dielectric structure, that provides electrical isolation between transistors 110. Dielectric material 121 of structure 120 may be any suitable material, such as a low-K dielectric (e.g., having a relative permittivity less than 5). For example, material 121 may be, or include, an oxide of silicon, such as silicon dioxide, which has a relative permittivity of 3.9. Isolation structure 120 may include other materials 121. Multiple materials may be employed, for example, to reduce the relative permittivity of structure 120 while maintaining other characteristic values, e.g., thermal conductivity, with sufficient margin to critical thresholds.

In the exemplary embodiment of FIG. 1, material 121 of structure 120 includes only silicon and oxygen and, notably, no detectable amount of nitrogen. Material 121 has an atomic composition of at least thirty percent silicon, at least thirty percent oxygen, and less than five percent nitrogen. In some embodiments, material 121 has an atomic composition of at least thirty percent silicon, at least fifty percent oxygen, and no detectable amount of nitrogen (e.g., less than five percent nitrogen), which may provide an advantageously low permittivity. In some embodiments, material 121 has an atomic composition of at least forty percent silicon, at least forty percent oxygen, and less than five percent nitrogen, which may provide a sufficiently low permittivity at a reduced cost (e.g., of time and/or money). Any suitable material(s) may be deployed.

Layer 122 is also an electrical insulator, but with a different composition, for example, that protects gate metals 114, 115 from an oxide material 121. Layers 122 may have a higher permittivity than dielectric material 121. Layers 122 may advantageously have a smaller thickness between material 121 and gate structure 112 than a thickness of dielectric material 121 between layers 122. For example, layers 122 may be of a material with a higher permittivity, but lacking oxygen. In many embodiments, layers 122 include nitrogen and lack oxygen. Layers 122 may be interface or liner layers 122 that provide a hermetic barrier over metals 114, 115, e.g., during a deposition of an oxide material 121 adjacent metals 114, 115.

In the example of FIG. 1, material 121 is between, and has a different composition than, layers 122, which each have a substantially same composition as the other layer 122. Layers 122 have an atomic composition of at least 30 percent silicon, at least 30 percent nitrogen, and no detectable amount of oxygen (e.g., less than five percent oxygen). In some embodiments, layers 122 have an atomic composition of at least 25 percent silicon, at least 40 percent nitrogen, and no detectable amount of oxygen (e.g., less than five percent oxygen), which may provide an advantageously impermeable barrier to oxygen (e.g., from material 121). In some embodiments, layers 122 have an atomic composition of at least twenty percent silicon, at least 45 percent nitrogen, and less than five percent oxygen, which may provide a sufficiently low impermeability at a reduced cost (e.g., of time and/or money). Any suitable material(s) and composition may be deployed.

Layers 122 may be of any suitable thickness, for example, of sufficient impermeability to reactive oxygen species or other potentially damaging substances. For a given space, e.g., device pitch for adjacent transistors, a thickness of layer 122 may interact with a dimension of isolation structure 120 (e.g., material 121). A minimal thickness of layer 122 may advantageously provide more space for a low-K dielectric material 121 between adjacent gate structures 112. In some embodiments, layer 122 has a thickness of approximately 2 nm. Risk of damage from exposure to oxygen, etc., may be most acute during deposition, for example, at elevated temperatures or other conditions of increased reactivity. As such, various deposition methods may compel various thicknesses (or compositions) of layers 122. In some embodiments, layer 122 has a thickness of 3 nm or more, e.g., to protect against oxidation, etc., of metals 114, 115 during deposition of material 121.

Gate structures 112 between intervening layers 122 are over channel regions 111. Regions 111 may have any composition suitable for a channel of a FET. In some examples, the channel material of region 111 is substantially silicon. In other embodiments, channel material includes germanium (e.g., Si_{1-X}Ge_{X}, Ge_{1-X}Sn_{X}, or substantially pure Ge). In some embodiments, channel region 111 includes a transition metal and a chalcogen. The transition metal may be any transition metal such as any element of groups 4 through 11, the group 3 elements scandium and yttrium, and the inner transition metals (e.g., f-block lanthanide and actinide series). Notable transition metals are molybdenum and tungsten. The chalcogen may be sulfur, selenium, and tellurium. In still other embodiments, channel region 111 includes one or more metals and oxygen (i.e., metal oxide semiconductor), such as, but not limited to, indium gallium zinc oxide (IGZO).

The channel material of region 111 is advantageously substantially monocrystalline. In some embodiments where channel region 111 is substantially pure silicon, the crystallinity of channel region 111 is cubic with a top surface having crystallographic orientation of (100), (111), or (110), for example. Other crystallographic orientations are also possible. Channel region 111 may also be polycrystalline or amorphous, for example in certain metal chalcogen and/or metal oxide embodiments.

Gate structures 112 between isolation structures 120 and intervening layers 122 include gate dielectrics 113. Gate dielectric 113 provides electrical insulation between channel regions 111 and gate metal 114. Gate dielectric 113 may include more than one layer. Gate dielectric 113 may be of any suitable material(s). The one or more layers of gate dielectric 113 may include a silicon oxide (such as silicon dioxide, SiO₂), a silicon oxynitride, etc. Advantageously, gate dielectric 113 includes a high-K dielectric (for example, having a relative permittivity or dielectric constant over 6). A high-k dielectric material may include one or more of various elements, such as hafnium, silicon, oxygen, titanium, tantalum, lanthanum, aluminum, zirconium, barium, strontium, yttrium, lead, scandium, niobium, and zinc. Gate dielectric 113 may include a dopant, e.g., for elevated permittivity.

Gate structure 112 may include multiple metals 114, 115, for example, in multiple layers, on and over gate dielectric 113. Gate structure 112 may include at least one of a p-type work function metal or an n-type work function metal, depending on whether the transistor is a p- or n-type metal oxide semiconductor (MOS) transistor. In the illustrative embodiments, gate structure 112 includes a stack of two or more metal layers, where one or more metal layers are work function metal layers (including at least gate liner metal 114), and at least one metal layer is a fill metal layer (including at least gate bulk metal 115). For a p-type MOS (PMOS) transistor, metals that may be used for the gate electrode include, but are not limited to, ruthenium, palladium, platinum, cobalt, nickel, and conductive metal oxides, e.g., ruthenium oxide. A p-type metal layer enables the formation of a PMOS gate electrode with a work function that is between about 4.9 eV and about 5.2 eV. For an n-type MOS (NMOS) transistor, metals that may be used for the gate electrode include, but are not limited to, hafnium, zirconium, titanium, tantalum, aluminum, alloys of these metals, and carbides of these metals, such as hafnium carbide, zirconium carbide, titanium carbide, and tantalum carbide. An n-type metal layer enables the formation of an NMOS gate electrode with a work function that is between about 3.9 eV and about 4.2 eV. Though not illustrated differently (e.g., not having apparently different liner metals 114), any of transistors 110 may have a conductivity type and liner metal 114 different than (e.g., complementary to) any other of transistors 110.

Transistors 110 are on or in substrate 199. Substrate 199 may be of any suitable material(s), including a crystalline material. For example, substrate 199 may be or include an IC die or wafer of any suitable semiconductor or other material. Substrate 199 may be of or include the material of channel regions 111 and/or fins 119 on or in substrate 199 (such as semiconductors Si, Ge, SiGe, GaAs, GaN, etc.). Substrate 199 may be of or include one or more other materials, for example, an insulator material (such as sapphire (e.g., Al₂O₃)) or semiconductor material (such as silicon carbide (e.g., SiC)). Substrate 199 may also include metals, dielectrics, dopants, and other materials commonly found in semiconductor substrates.

Electrical isolation 130, such as an STI, is over substrate 199, between fins 119 and transistors 110. Isolation 130 may prevent or minimize leakage current between adjacent devices or components on substrate 199, such as transistors 110, whose source and drain regions may be aligned (e.g., in the y-directions) with channel regions 111. Isolation 130 may be or include any suitable electrically insulating material, for example, an oxide (e.g., of silicon, such as silicon dioxide (SiO₂)). Isolation 130 may provide a platform for the deposition of other materials, such as those of gate metals 114, 115.

Gate metals 114, 115 are over isolation 130 and couple transistors 110 with shared gate structure 112. Gate liner metal 114 is conformally on all gate dielectrics 113 over the stacks of channel regions 111. Gate fill metal 115 is over (e.g., above and on either side of) each stack of channel regions 111, gate dielectric 113, and gate liner metal 114. In some embodiments, gate fill metal 115 is between liner metal 114 (between channel regions 111 and dielectric 113).

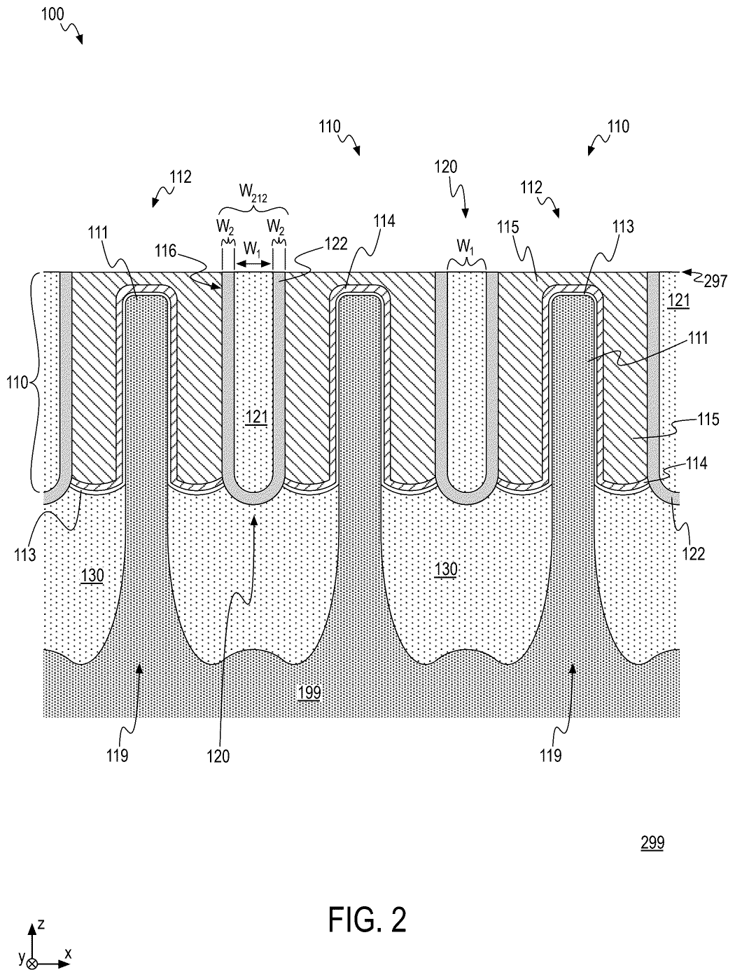

FIG. 2 illustrates a cross-sectional profile view of IC device 100 having adjacent nonplanar transistors 110 with gate structures 112 separated by isolation structures 120, in accordance with some embodiments. In the exemplary embodiments of FIG. 2, transistors 110 are FinFETs, and channel regions 111 are in fins 119 (extending in both y-directions, through the viewing plane), rather than nanoribbons. In many embodiments, IC device 100 (e.g., substrate 199) is coupled to another substrate 299 (such as a package substrate, motherboard, etc.) and a power supply (not shown) through substrate 299.

Many sizes and shapes of isolation structures 120 may be suitable. The size and shape of isolation structure 120 may be determined by the corresponding size and shape of an opening formed between adjacent transistors 110 and gate structures 112, for example, by a gate cut. As shown in FIG. 2, some isolation structures 120 may have vertical (or substantially vertical) aspects and be adjacent gate structures 112 with vertical (or substantially vertical) gate sidewalls 116. Some isolation structures 120 may have a tapered aspect with a wider top and narrower bottom, as in FIG. 1. Yet other embodiments may have a reverse taper with isolation structures 120 having a narrower top than bottom. Isolation structures 120 having virtually no taper (e.g., substantially vertical sides) or a reverse taper may require more controlled (e.g., slower) etches, for example, gate cuts between gate structures 112, as may etches (and isolation structures 120) more closely approaching channel regions 111. Accordingly, the need for a deeper isolation structure 120 (e.g., requiring a deeper etch of longer duration) may be balanced against the need for a wider isolation structure 120.

The depth of isolation structure 120 may vary with embodiments. As shown in FIG. 2, isolation structure 120 may be between gate structures 112 only to a bottom of gate structure 112, e.g., having minimal penetration or interface with STI 130. For example, an etch that forms an opening between adjacent transistors 110 and gate structures 112 may be only of metals 114, 115 and may not extend into (or significantly into) STI 130. At a bottom of isolation structure 120 over STI 130, intervening layers 122 between material 121 and adjacent gate structures 112 (i.e., layers 122 to both x-directions of material 121) are connected and form a continuous layer on both gate structures 112.

As previously described, a dimension of a low-K dielectric material 121 may be related (e.g., inversely) with a thickness or width of intervening layers 122. For example, a width W₁ of material 121 may be maximized by minimizing a thickness or width W₂ of layers 122, e.g., in embodiments when an x-dimension between gate structures 112 is set by layout (or other) considerations. In at least some such embodiments, the distance between gate structures 112 is equal to width W₁ of material 121 plus twice width W₂ of layers 122, and width W₁ of material 121 may be increased by depositing a thinner width W₂ of layers 122. (Width W₁ of material 121 plus twice width W₂ of layers 122 is shown as width W₂₁₂. Widths W₁, W₂, etc., may be defined or taken at a top surface 297 of structures 112 or 120.) In embodiments with deep and/or narrow aspects, the deposition of material 121 may be limited by an overly small width W₁ and/or an overly thick width W₂ of layer 122. In some embodiments, width W₁ of material 121 may be a minimum of twice the width W₂ of layer 122. For example, in some embodiments, width W₁ of material 121 is three times width W₂ of layer 122. In some such embodiments, width W₁ of material 121 is 9 nm, and width W₂ of layer 122 is 3 nm. Such dimensions may enable deposition of a width W₁ of low-K material 121 while ensuring a minimal barrier width W₂ of layer 122. Deposition of a narrow width W₁ of material 121 between widths W₂ of layer 122 may be enabled by shallow dimensions of isolation structure 120 (e.g., in the z-dimension), e.g., only down and not extending significantly into STI 130. In other embodiments, a width W₂ of layers 122 is 4 nm or larger, for example, with a wider width W₁ of material 121 or shallower isolation structure 120.

Substrate 299 may be any planar platform or host component, such as a package substrate. Substrate 299 may include dielectric and metallization structures. Substrate 299 may mechanically support, and electrically couple to, IC device 100. At least one side of substrate 299 includes interconnect interfaces, e.g., for soldering or direct bonding to one or more devices 100. The opposite side of substrate 299 may include similar interfaces or, e.g., copper pads for socketing or solder bumps for bonding to another host component, for example, a printed circuit board. Substrate 299 may be any platform with interconnect interfaces, such as a package substrate or interposer, an IC die, etc. Substrate 299 may itself be a die or an insulating substrate. Substrate 299 may bond to any platform, such as a package substrate or interposer, an IC die, etc.

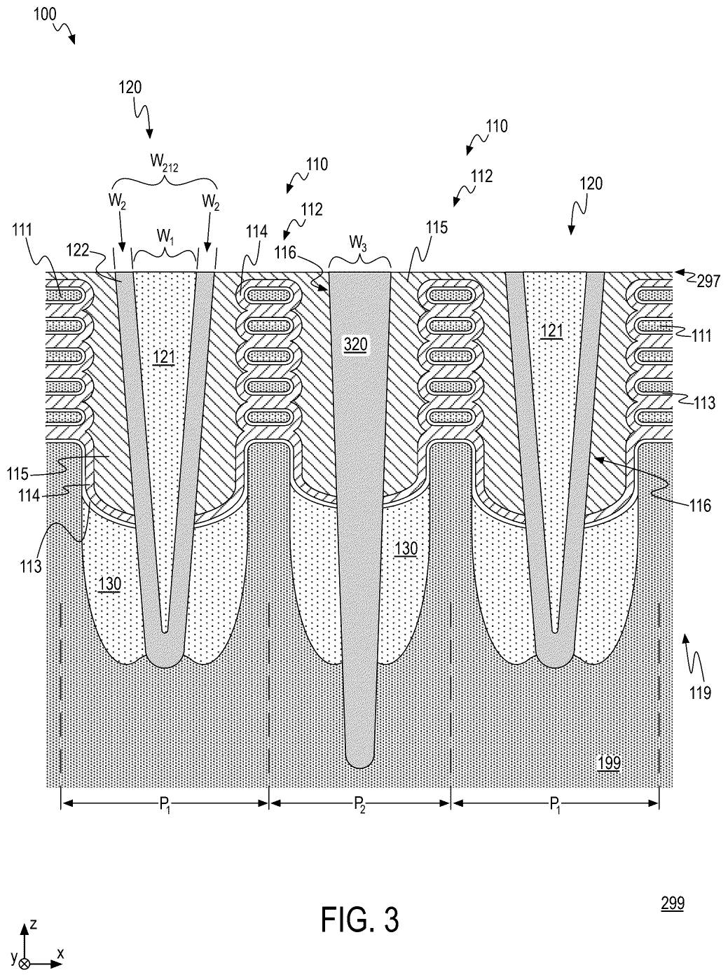

FIG. 3 illustrates a cross-sectional profile view of IC device 100 having adjacent nonplanar transistors 110 with gate structures 112 separated by various isolation structures 120, 320, in accordance with some embodiments. Some of transistors 110 and gate structures 112 are separated by isolation structures 120 as previously described. Some of transistors 110 and gate structures 112 are separated by isolation structures 320, which have different structures and compositions than isolation structures 120. Isolation structures 320 have a substantially uniform composition throughout, rather than a bulk or fill material 121 enclosed in a liner layer 122.

In the exemplary embodiments of FIG. 3, pairs of transistors 110 and gate structures 112 with a center-to-center pitch P₁ are separated by isolation structures 120, and pairs of transistors 110 and gate structures 112 with a center-to-center pitch P₂ are separated by isolation structures 320. In some embodiments, isolation structure 320 has a shorter diameter or width W₃ than a diameter or width of isolation structures 120. (The diameter or width of isolation structures 120 may be width W₂₁₂, equal to width W₁ of material 121 plus twice width W₂ of layers 122, that distance between gate structures 112. Diameters or widths W₁, W₂, W₃, etc., may be defined or taken at a top surface 297 of structures 112, 120, 320, etc., e.g., at a maximum width for tapered structures 120, 320. The term “diameter” refers to a width or thickness of a structure centered on, or symmetrical about, an axis, at least in the viewing plane. Use of the term “diameter” may refer to rectangular or other shapes, with rounded corners or not, and does not necessarily imply that a structure has a circular shape or cross-sectional area.)

In some embodiments, isolation structures 320 having shorter widths W₃ separate pairs of transistors 110 and gate structures 112 with smaller pitches P₂ (e.g., pitches P₂ are shorter than pitches P₁ between pairs of transistors 110 and gate structures 112 separated by isolation structures 120). Such a narrower width W₃ may be too narrow for deposition of a low-K material 121 between layers 122, e.g., in an opening within or enclosed by a continuous layer 122. Isolation structures 320 may be deployed when only such a narrower width W₃ is available between transistors 110. For example, in some embodiments, isolation structures 320 (e.g., consisting of a single dielectric material) have widths W₃ less than 30 nm. In some such embodiments, isolation structures 120 have widths W₂₁₂ greater than 30 nm. In some embodiments, isolation structures 320 have widths W₃ less than 75% or three-quarters of widths W₂₁₂ of isolation structures 120.

Isolation structure 320 may have similarities with structure 120, including functional similarities. Isolation structure 320 is an electrically insulating (e.g., dielectric) structure that provides electrical isolation between transistors 110. Isolation structure 320 is on gate sidewalls 116 of adjacent transistors 110 and gate structures 112. Isolation structure 320 may have a single composition, e.g., such that structure 320 may be advantageously be formed or deposited without causing certain damage, such as oxidation, to adjacent gate metals 114, 115. For example, isolation structure 320 may have a same composition as intervening layers 122. In some embodiments, isolation structure 320 includes nitrogen. In some such embodiments, structure 320 includes silicon. In some such embodiments, structure 320 includes silicon. In some embodiments, structure 320 and layers 122 have an atomic composition of at least fifty percent silicon, at least twenty percent nitrogen, and less than five percent oxygen. Such a composition may provide a low impermeability to oxygen species and a sufficiently low relative permittivity. Other materials may be deployed. Structure 320 may be of any suitable material.

Isolation structures 120, 320 may be deployed together in IC devices 100 strategically. For example, isolation structures 320 (e.g., consisting of a single material and having a shorter width W₃) may be deployed where parasitic capacitance constraints are less strict, such as between transistors 110 in less-critical speed or timing paths. Such transistors 110 may be laid out more closely together for this reason. As in FIG. 3, isolation structures 320 may be deployed between transistors 110 with shorter gate sidewalls 116, which may reduce capacitance dependencies on low-permittivity dielectrics.

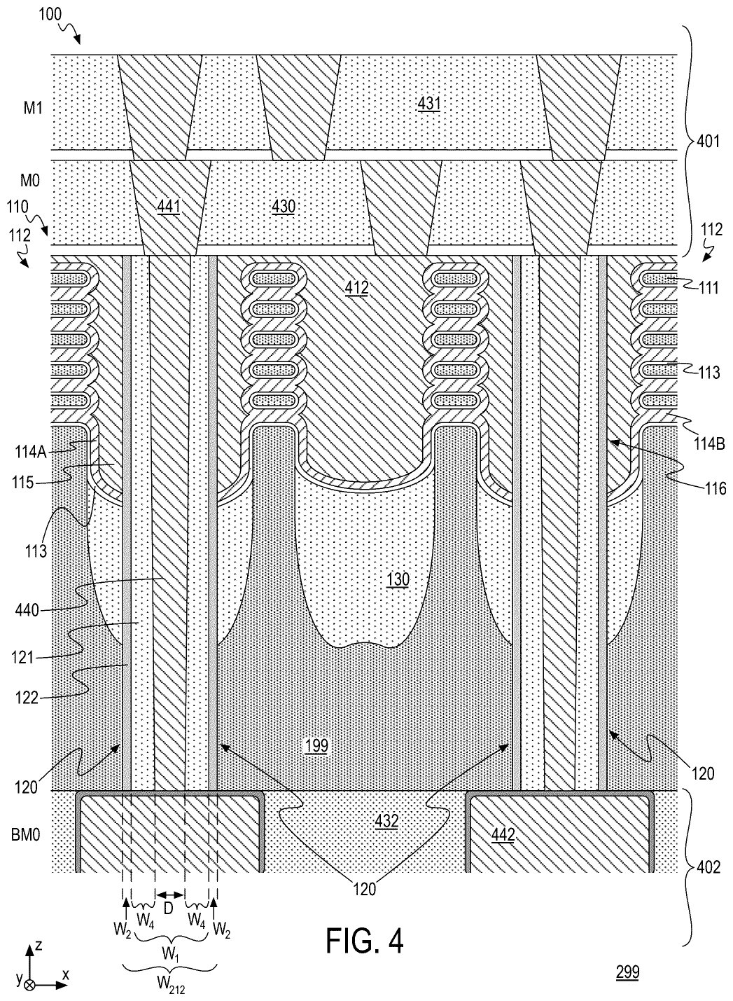

FIG. 4 illustrates a cross-sectional profile view of IC device 100 having isolation structures 120 between adjacent transistors 110 and vias 440, in accordance with some embodiments. Isolation structures 120 are between adjacent transistors 110 and separate transistors 110 and vias 440. Metallic vias 440 are each between intervening layers 122, in contact with isolation structures 120 at dielectric materials 121. Intervening layers 122 are on gate structures 112 (e.g., in contact with gate sidewalls 116), and each intervening layer 122 is between a via 440 and a gate structure 112. Vias 440 and transistors 110 are all between interconnect structures 401, 402 on front- and back-sides of substrate 199.

Vias 440 extend between and couple upper and lower interconnect structures 401, 402, over and under gate structures 112, respectively. Interconnect structures 401, 402 are metallization structures with one or more layers of electrical interconnects (such as metal vias and lines or trenches) through electrically insulating material(s), e.g., low-K dielectric material. Upper interconnect structure 401 includes layers M0, M1, etc., over transistors 110. Layers M0, M1 include vias 441 through dielectric materials 430, 431, respectively. Lower interconnect structure 402 includes at least layer BM0, etc., under transistors 110. Layer BM0 includes metal lines or vias 442 through dielectric material 432. Upper interconnect structure 401 is in contact with gate structures 112, 412 (e.g., at vias 441). Upper interconnect structure 401 is in contact with vias 440 at vias 441. Vias 440 extend between gate structures 112 and contact lower interconnect structure 402 (e.g., at lines or vias 442) under gate structures 112. Vias 440 may couple power from substrate 299, through a backside power delivery network (e.g., interconnect structure 402), and to a frontside power delivery network (e.g., interconnect structure 401).

Interconnect structures 401, 402 and lines or vias 440, 441, 442 may include any suitable (e.g., electrically conductive) materials. Such conductive materials may be conventional (or other) metals, etc., such as those typically used in interconnect structures. In many embodiments, interconnect structures 401, 402 employ copper. In many embodiments, other metals are deployed at lower levels, such as layers M1, M0, and BM0. Besides copper, suitable and notable metals that may be utilized in conductive structures (including in vias 440) include, but are not limited to, tungsten, cobalt, ruthenium, molybdenum, nickel, titanium, tantalum, etc., including in alloys (e.g., titanium nitride, etc.). In many embodiments, vias 440 include one or more of these listed (or other) metals.

In some embodiments, a via 440 with diameter D is through an isolation structure 120 (for example, when layers 122 on either side of via 440 are together a single, continuous layer 122, e.g., around material 121 and via 440 in the y-directions as well, and when a continuous layer of dielectric material 121 contacting via 440 similarly encloses via 440). In such embodiments, width W₁ may be a diameter of a layer of continuous material 121 that includes two thicknesses or widths W₄ of a layer of material 121 around via 440, and isolation structure 120 has a diameter or width W₂₁₂. In such embodiments, width W₂₁₂ may also be a diameter of a continuous layer 122 (e.g., with thickness or width W₂) around and in contact with material 121. In other embodiments, layers 122 and a layer of material 121 are interrupted, e.g., in front and behind the viewing plane of FIG. 4 (in both y-directions). In some such embodiments, distinct isolation structures 120 (with a combined width of width W₂ plus width W₄) are on both sides of a via 440, and via 440 is between isolation structures 120. Such distinct isolation structures 120 on either side of via 440 may each have a single layer 122 between material 121 and a gate structure 112 of an adjacent transistor 110.

A thickness or width of isolation structure 120 (e.g., width W₄ of dielectric material 121) is between via 440 and intervening layer 122. A thickness or width W₂ of intervening layer 122 is between, and separates, gate structure 112 (e.g., sidewall 116) and the thickness or width W₄ of dielectric material 121 of isolation structure 120.

As described, a thickness of low-K dielectric material 121 (e.g., width W₄) may advantageously be maximized relative to width W₂ of a thinner liner layer 122 around material 121. In some embodiments, width W₄ of material 121 is twice width W₂ of layer 122, which may maximize width W₄ of material 121 and minimize a parasitic capacitance between via 440 and an adjacent gate sidewall 116. In some embodiments, width W₄ of material 121 is three times width W₂ of layer 122, which may ensure a sufficient impenetrability of layer 122.

In embodiments having vias 440 separated from transistors 110 by isolation structures 120 (e.g., material 121 and layer 122), low-K dielectric material 121 may advantageously have a significant width W₄ relative to diameter D of via 440. (However, a minimum diameter D of via 440 may be required to guarantee necessary electrical conductance through via 440.) For example, width W₄ of material 121 may be more than half of diameter D of via 440. In some embodiments, diameter D of via 440 is more than one-and-a-half times, but less than twice, the width W₄ of dielectric material 121. For example, in some embodiments, isolation structure 120 has a thickness or width of less than 10 nm (e.g., 9 nm) on both sides of via 440 (e.g., width W₄ of material 121), between via 440 and both intervening layers 122 (e.g., in contact with material 121). In some such embodiments, both intervening layers 122 have a width W₂ of less than 4 nm (e.g., 3 nm) between gate structure 112 (e.g., sidewall 116) and material 121. In some such embodiments, diameter D of via 440 is less than 20 nm (e.g., 16 nm).

The materials of isolation structures 120 may be much as previously described. For example, low-K dielectric material 121 may include silicon and oxygen, and intervening layers 122 may include silicon and nitrogen, in the proportions described at least at FIG. 1.

In some embodiments, some transistors 110 have shared gate structures 412 over unshared channel regions 111. For example, two transistors 110 include shared gate structure 412 but separate stacks of nanoribbon channel regions 111.

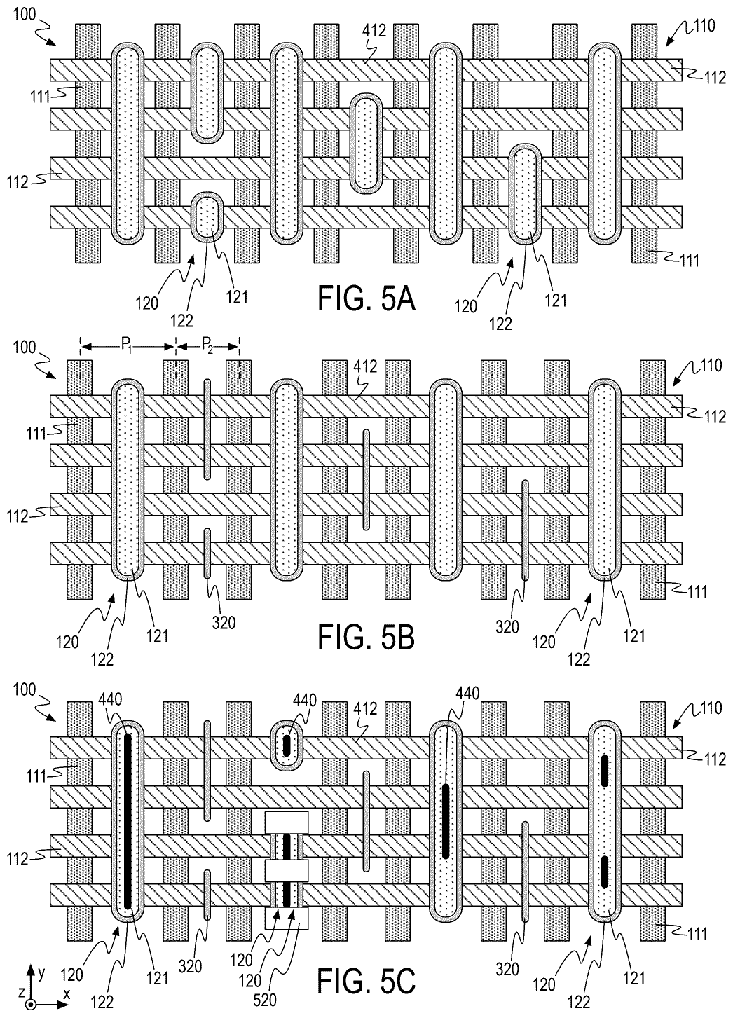

FIGS. 5A, 5B, and 5C illustrate plan views of IC device 100 having isolation structures 120, 320 between adjacent transistors 110 and vias 440, in accordance with some embodiments. For illustrative purposes, some structures (such as contacts, source and drain regions, etc.) are not shown.

FIG. 5A shows parallel channel regions 111 (e.g., in nanoribbons or fins, extending in the y-direction). Parallel metal gate structures 112, 412 are over regions 111 and extend in the x-direction, but are interrupted by isolation structures 120. Transistors 110 are where gate structures 112, 412 are over channel regions 111. Gate structures 412 are those over multiple channel regions 111.

Isolation structures 120 are between, and separate some gate structures 112, 412. Some isolation structures 120 extend in the y-direction through or between multiple pairs of gate structures 112, 412. Some isolation structures 120 may also extend through source and drain regions (not shown) parallel with and between gate structures 112, 412.

The plan view of FIG. 5A illustrates isolation structures 120 having continuous liner layers 122 around structures of dielectric material 121. Liner layers 122 surround and enclose dielectric material 121 (in at least the x- and y-directions). Intervening liner layers 122 form a continuous layer 122 on (e.g., in contact with) gate structures 112, 412 to both sides of isolation structures 120 and layers 122.

FIG. 5B illustrates a device 100 similar to device 100 of FIG. 5A. Similar parallel channel regions 111 extend in the y-direction, and parallel gate structures 112, 412 are over regions 111 and extend in the x-direction. Notably, gate structures 112, 412 are interrupted by isolation structures 120, 320. Isolation structures 320 extend in the y-direction through or between pairs of gate structures 112 over pairs of channel regions 111 with smaller pitches P₂ (e.g., smaller or shorter than pitches P₁ between regions 111 corresponding to isolation structures 120). Isolation structures 320 are on (e.g., in contact with) gate structures 112 to both sides of isolation structures 320.

FIG. 5C shows a device 100 similar to device 100 of FIG. 5B. Similar gate structures 112, 412 are over similar regions 111 and are interrupted by similar isolation structures 120, 320. Notably, some of isolation structures 120 enclose vias 440. Vias 440, which include a metallic material, are in contact with isolation structures 120 (e.g., at dielectric material 121) and between intervening layers 122. Intervening layers 122 are between via 440 and abutting gate structures 112. Most isolation structures 120 include a continuous layer of dielectric material 121 around, and in contact with, the corresponding via 440. Liner layers 122 are continuous in most isolation structures 120 and around most layers of dielectric material 121.

In some embodiments, layers 122 and layers of material 121 are interrupted, e.g., by insulating spacer structures 520 to both y-directions of vias 440. In some such embodiments, distinct isolation structures 120 (each with a single layer 122 and single layer of material 121) are on both sides of a via 440, and via 440 is between those isolation structures 120.

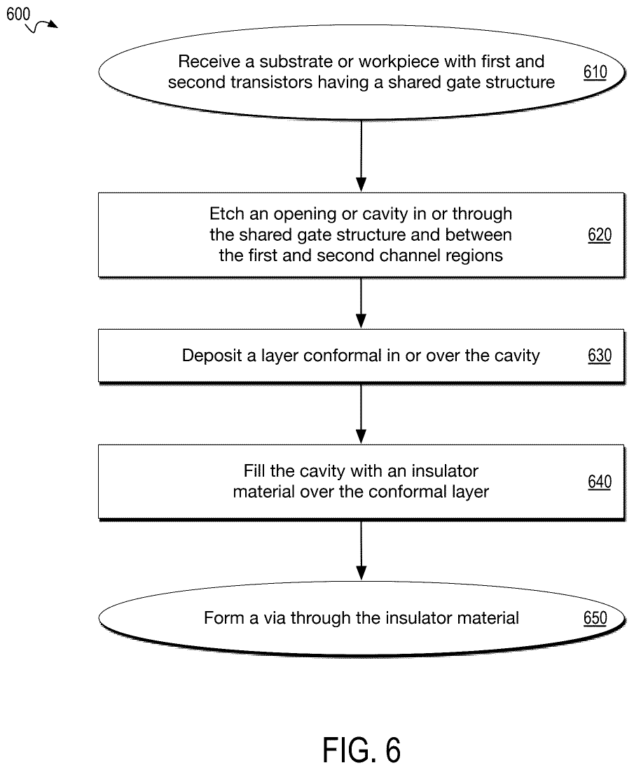

FIG. 6 is a flow chart of methods 600 for forming an IC device with dielectric isolation structures between and separating transistor gate structures, in accordance with some embodiments. Methods 600 include operations 610-650. Some operations shown in FIG. 6 are optional. Additional operations may be included. FIG. 6 shows an example sequence, but the operations can be done in other orders as well, and some operations may be omitted. Some operations can also be performed multiple times before other operations are performed. For example, multiple cavities may be etched through one or more shared gate structures before filling the cavities with insulator material. Some operations may be included within other operations so that the number of operations illustrated FIG. 6 is not a limitation of the methods 600.

Methods 600 begin at operation 610 with receiving a substrate or workpiece including multiple transistors having a shared gate structure. For example, the transistors may be nonplanar transistors, each with a separate channel region in a fin or stack of nanoribbons, and the shared gate structure may be a gate structure over the separate channel regions (e.g., fins or nanoribbons) of at least two transistors on the substrate or workpiece.

In some embodiments, the shared gate structure is a shared metal gate structure. In some such embodiments, the transistors and shared metal gate structure have the components described at, e.g., FIG. 1 or 2. For example, the transistors may separately include channel regions in nanoribbons (as in FIG. 1) or fins (as in FIG. 2), and the shared metal gate structure may include a gate dielectric and liner and bulk gate metals. Notably, isolation structures between gate structures may be absent.

Methods 600 continue at operation 620 with etching an opening through the shared gate structure and between the separate channel regions of the different transistors. In some embodiments, the etching is a gate cut etch, and the opening separates the shared gate structure into at least two gate structures. The opening will form gate sidewalls and will be filled by the isolation structure to separate adjacent gate structures, so the size and shape of the opening may affect eventual device performance, for example, by affecting parasitic capacitances between adjacent transistors.

Any suitable etch may form the opening. For example, well-controlled etches (such as an atomic layer etch (ALE)) may be employed as necessary, e.g., to carefully etch gate sidewalls with desired profiles (such as substantially vertical profiles) or with well-resolved and repeatable critical dimensions (CDs). For example, such a well-controlled etch may be utilized to cut a metal gate to have a vertical (or very nearly vertical) sidewall very close (e.g., with an exceptionally tight CD) to a channel region or gate dielectric on a channel. Such well-controlled etches may take more processing time and other etches may be used for other, less tightly constrained gate cuts.

Different etches may employ various chemistries, temperatures, powers (e.g., radio frequency (RF) power), durations, etc., to achieve desired gate cut profiles. For example, a directional plasma etch may break though targeted passivation, e.g., in a downward direction, orthogonal to an IC die or wafer, while leaving passivation substantially undisturbed on untargeted surfaces, e.g., sidewalls. Such an etch may realize different etch profiles depending on the power and chemistries utilized (whether of etchants or mask layers, etc.). One or more etches may be used alternatively or in combination to further tailor gate cut profiles. Such combinations or other etch characteristics may result in slight or severe etch tapers, in substantially vertical etches (e.g., with virtually no taper), or even in reverse-taper etches. Any such variations in etch parameters and consequent variations in etch profiles may affect eventual device performance by influencing the size and shape of the opening or cavity between gate structures.

Methods 600 continue by depositing a conformal layer over a surface of the opening at operation 630. The conformal layer may form a barrier, such as a hermetic liner, including on the gate sidewall. As such, the conformal layer may be formed with appropriate control, of suitable material(s), and to a sufficient thickness to ensure protection of the gate structure. The conformal layer may be over any and all exposed surface(s) of the opening, including but not limited to the gate sidewall.

In some embodiments, the conformal layer is deposited by an atomic layer deposition (ALD), which may provide both satisfactory conformality and precise control of layer thickness. Other means of deposition may be used.

Such deposition may enable the formation of an intervening or liner layer as described at least at FIGS. 1 and 2. For example, a conformal liner layer of silicon and nitrogen may be deposited to a thickness of less than 4 nm. While thicker barrier layers may ensure impenetrability (e.g., against reactive oxygen species), thinner layers may reduce parasitic capacitances and improve device performance. In some embodiments, a conformal liner layer of silicon and nitrogen may be deposited, e.g., by an ALD, to a thickness of 2 or 3 nm.

In some embodiments, conformal deposition of the liner layer is concurrent with the deposition and fill of, e.g., narrow or deep isolation structures having uniform compositions (i.e., without liner layers).

Methods 600 continue with filling the opening with an insulator material over the conformal layer at operation 640. This bulk insulator material is advantageously a low-K dielectric material. To maximize the benefit of the low-K dielectric material, for example, in reducing parasitics between transistors, the bulk low-K dielectric material may be grown much thicker than the conformal liner layer. In some embodiments, the insulator material is grown or deposited to a thickness more than twice the thickness of the conformal layer. In some such embodiments, the insulator material is grown to a thickness more than ten times the thickness of the conformal layer, which may be necessary to allow sufficient space for a via through the insulator material. Such growth may enable the formation of the isolation structure dielectric material as described at least at FIGS. 1 and 2 (e.g., of material 121). For example, in some embodiments, the insulator material includes silicon and oxygen and at the proportions described at FIGS. 1 and 2.

Methods 600 continue at optional operation 650 by forming a via through the insulator material. The via formation may be by any suitable means, for example, by a directional plasma etch. In some embodiments, the via is a through-silicon via (TSV). In some such embodiments, the via is a nano-TSV, for example, with a via diameter of less than 20 nm. Such a TSV may extend through the insulator material, e.g., the low-K dielectric material, between and beyond the gate structures and transistors, and through the received substrate to a backside of the substrate.

The via may include any suitable material. In some embodiments, the via includes a metallic material, such as any metal described at FIG. 4 or other metal(s).

In some embodiments, the via is coupled to interconnect structures on one or both of the front- and back-sides of the received substrate. The interconnect structures may be metallization structures (such as those described at FIG. 4), which may include conductive lines and vias in and between layers of the interconnect structures. In some embodiments, the via is coupled to a frontside interconnect structure over the multiple gate structures. In some embodiments, the via is coupled to a backside interconnect structure under the multiple gate structures (i.e., the multiple gate structures may be over the backside interconnect structure). The via may be coupled to the front- and back-side interconnect structures by any suitable means. For example, the frontside interconnect structure may contact a TSV at a top of the via, e.g., at a metal layer M0, as the frontside interconnect structure is built up over the substrate. The backside interconnect structure may contact a TSV at an opposite end of the via, e.g., at a metal layer BM0, after the substrate is inverted, and as the backside interconnect structure is built up over the substrate.

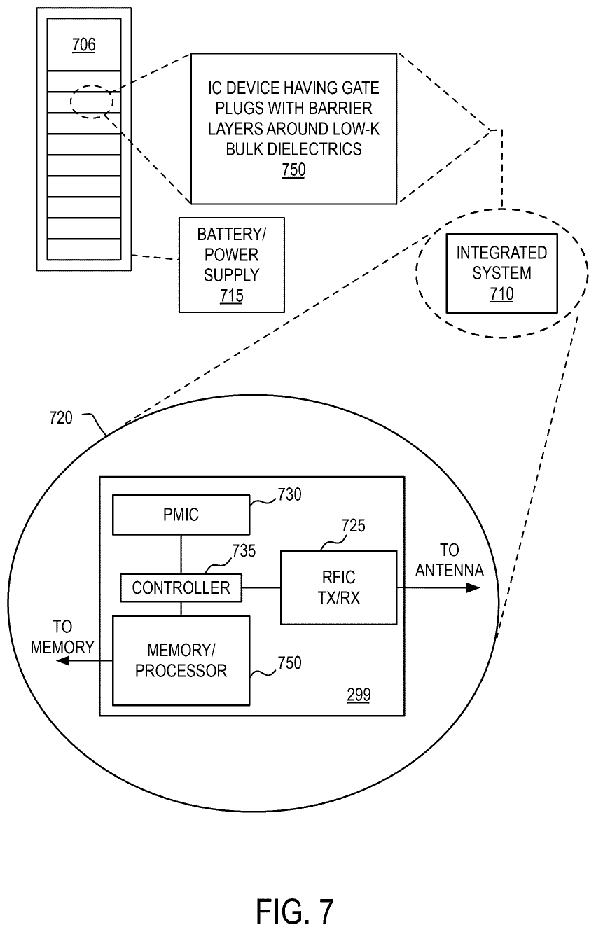

FIG. 7 illustrates a diagram of an example data server machine 706 employing an IC device having gate plugs with barrier layers around bulk low-K dielectric materials, in accordance with some embodiments. Server machine 706 may be any commercial server, for example, including any number of high-performance computing platforms disposed within a rack and networked together for electronic data processing, which in the exemplary embodiment includes one or more devices 750 with gate plugs having barrier layers around bulk low-K dielectric materials.

Also as shown, server machine 706 includes a battery and/or power supply 715 to provide power to devices 750, and to provide, in some embodiments, power delivery functions such as power regulation. Devices 750 may be deployed as part of a package-level integrated system 710. Integrated system 710 is further illustrated in the expanded view 720. In the exemplary embodiment, devices 750 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 750 is a microprocessor including a static RAM (SRAM) cache memory. As shown, device 750 may be an IC device having gate plugs with barrier layers around bulk low-K dielectric materials, as discussed herein. Device 750 may be further coupled to (e.g., communicatively coupled to) a board, an interposer, or a substrate 299 along with, one or more of a power management IC (PMIC) 730, RF (wireless) IC (RFIC) 725 including a wideband RF (wireless) transmitter and/or receiver (TX/RX) (e.g., including a digital baseband and an analog front end module further includes a power amplifier on a transmit path and a low noise amplifier on a receive path), and a controller 735 thereof. In some embodiments, RFIC 725, PMIC 730, controller 735, and device 750 include gate plugs with barrier layers around bulk low-K dielectric materials.

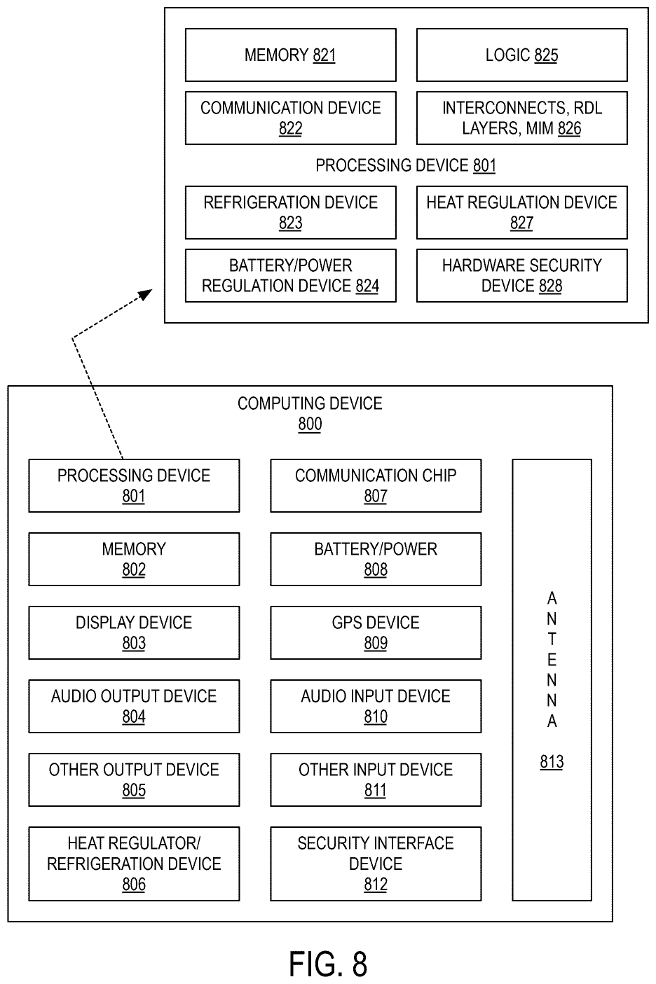

FIG. 8 is a block diagram of an example computing device 800, in accordance with some embodiments. For example, one or more components of computing device 800 may include any of the devices or structures discussed herein. A number of components are illustrated in FIG. 8 as being included in computing device 800, but any one or more of these components may be omitted or duplicated, as suitable for the application. In some embodiments, some or all of the components included in computing device 800 may be attached to one or more printed circuit boards (e.g., a motherboard). In some embodiments, various ones of these components may be fabricated onto a single system-on-a-chip (SoC) die. Additionally, in various embodiments, computing device 800 may not include one or more of the components illustrated in FIG. 8, but computing device 800 may include interface circuitry for coupling to the one or more components. For example, computing device 800 may not include a display device 803, but may include display device interface circuitry (e.g., a connector and driver circuitry) to which display device 803 may be coupled. In another set of examples, computing device 800 may not include an audio output device 804, other output device 805, global positioning system (GPS) device 809, audio input device 810, or other input device 811, but may include audio output device interface circuitry, other output device interface circuitry, GPS device interface circuitry, audio input device interface circuitry, audio input device interface circuitry, to which audio output device 804, other output device 805, GPS device 809, audio input device 810, or other input device 811 may be coupled.

Computing device 800 may include a processing device 801 (e.g., one or more processing devices). As used herein, the term “processing device” or “processor” indicates a device that processes electronic data from registers and/or memory to transform that electronic data into other electronic data that may be stored in registers and/or memory. Processing device 801 may include a memory 821, a communication device 822, a refrigeration device 823, a battery/power regulation device 824, logic 825, interconnects 826 (i.e., optionally including redistribution layers (RDL) or metal-insulator-metal (MIM) devices), a heat regulation device 827, and a hardware security device 828.

Processing device 801 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 800 may include a memory 802, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 802 includes memory that shares a die with processing device 801. This memory may be used as cache memory and may include embedded dynamic random-access memory (eDRAM) or spin transfer torque magnetic random-access memory (STT-MRAM).

Computing device 800 may include a heat regulation/refrigeration device 806. Heat regulation/refrigeration device 806 may maintain processing device 801 (and/or other components of computing device 800) at a predetermined low temperature during operation.

In some embodiments, computing device 800 may include a communication chip 807 (e.g., one or more communication chips). For example, the communication chip 807 may be configured for managing wireless communications for the transfer of data to and from computing device 800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 807 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 807 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network.

Communication chip 807 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 807 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 807 may operate in accordance with other wireless protocols in other embodiments. Computing device 800 may include an antenna 813 to facilitate wireless communications and/or to receive other wireless communications (such as AM or FM radio transmissions).

In some embodiments, communication chip 807 may manage wired communications, such as electrical, optical, or any other suitable communication protocols (e.g., the Ethernet). As noted above, communication chip 807 may include multiple communication chips. For instance, a first communication chip 807 may be dedicated to shorter-range wireless communications such as Wi-Fi or Bluetooth, and a second communication chip 807 may be dedicated to longer-range wireless communications such as GPS, EDGE, GPRS, CDMA, WiMAX, LTE, EV-DO, or others. In some embodiments, a first communication chip 807 may be dedicated to wireless communications, and a second communication chip 807 may be dedicated to wired communications.

Computing device 800 may include battery/power circuitry 808. Battery/power circuitry 808 may include one or more energy storage devices (e.g., batteries or capacitors) and/or circuitry for coupling components of computing device 800 to an energy source separate from computing device 800 (e.g., AC line power).

Computing device 800 may include a display device 803 (or corresponding interface circuitry, as discussed above). Display device 803 may include any visual indicators, such as a heads-up display, a computer monitor, a projector, a touchscreen display, a liquid crystal display (LCD), a light-emitting diode display, or a flat panel display, for example.

Computing device 800 may include an audio output device 804 (or corresponding interface circuitry, as discussed above). Audio output device 804 may include any device that generates an audible indicator, such as speakers, headsets, or earbuds, for example.

Computing device 800 may include an audio input device 810 (or corresponding interface circuitry, as discussed above). Audio input device 810 may include any device that generates a signal representative of a sound, such as microphones, microphone arrays, or digital instruments (e.g., instruments having a musical instrument digital interface (MIDI) output).

Computing device 800 may include a GPS device 809 (or corresponding interface circuitry, as discussed above). GPS device 809 may be in communication with a satellite-based system and may receive a location of computing device 800, as known in the art.

Computing device 800 may include other output device 805 (or corresponding interface circuitry, as discussed above). Examples of the other output device 805 may include an audio codec, a video codec, a printer, a wired or wireless transmitter for providing information to other devices, or an additional storage device.

Computing device 800 may include other input device 811 (or corresponding interface circuitry, as discussed above). Examples of the other input device 811 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 800 may include a security interface device 812. Security interface device 812 may include any device that provides security measures for computing device 800 such as intrusion detection, biometric validation, security encode or decode, access list management, malware detection, or spyware detection.

Computing device 800, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-8. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a first transistor including a first gate structure over one or more first nanoribbons, the first gate structure including a first gate sidewall, a second transistor adjacent the first transistor and including a second gate structure over one or more second nanoribbons, the second gate structure including a second gate sidewall, a dielectric structure between the first and second transistors, and first and second intervening layers, wherein the first intervening layer is on the first gate sidewall, the second intervening layer is on the second gate sidewall, and the dielectric structure is between the first and second intervening layers.

In one or more second embodiments, further to the first embodiments, the apparatus also includes a via in contact with the dielectric structure and between the first and second intervening layers, wherein the via includes a metallic material, and the first or second intervening layer is between the via and the first or second gate structure.

In one or more third embodiments, further to the first or second embodiments, a first metallization structure is over and in contact with the first or second gate structure, and the via extends between the first and second gate structures and contacts a second metallization structure under the first or second gate structure.

In one or more fourth embodiments, further to the first through third embodiments, a first thickness of the dielectric structure is between the via and the first or second intervening layer, a diameter of the via is less than twice the first thickness of the dielectric structure, and the first thickness is greater than twice a second thickness of the first or second intervening layer. 5 the dielectric structure includes a first thickness of less than 10 nm between the via and the first intervening layer, and the first thickness of less than 10 nm between the via and the second intervening layer,

In one or more fifth embodiments, further to the first through fourth embodiments, the dielectric structure includes a first thickness of less than 10 nm between the via and the first intervening layer, and the first thickness of less than 10 nm between the via and the second intervening layer, the first intervening layer includes a second thickness of less than 4 nm between the first gate structure and the dielectric structure, the second intervening layer includes the second thickness of less than 4 nm between the second gate structure and the dielectric structure, and the via has a diameter of less than 20 nm.

In one or more sixth embodiments, further to the first through fifth embodiments, the first and second intervening layers include a substantially same composition, including silicon and nitrogen, and the dielectric structure includes silicon and oxygen. 7 the first and second intervening layers include a first atomic composition of at least forty percent silicon, at least fifteen percent nitrogen, and less than five percent oxygen, and the dielectric structure includes a second atomic composition of at least thirty percent silicon, at least thirty percent oxygen, and less than five percent nitrogen.

In one or more seventh embodiments, further to the first through sixth embodiments, the first and second intervening layers include a first atomic composition of at least forty percent silicon, at least fifteen percent nitrogen, and less than five percent oxygen, and the dielectric structure includes a second atomic composition of at least thirty percent silicon, at least thirty percent oxygen, and less than five percent nitrogen.

In one or more eighth embodiments, further to the first through seventh embodiments, the first and second intervening layers form a continuous layer on both the first and second gate structures.

In one or more ninth embodiments, further to the first through eighth embodiments, the dielectric structure is a first dielectric structure, and the apparatus also includes a third transistor including a third gate structure over one or more third nanoribbons, the third gate structure including a third gate sidewall, and a second dielectric structure between the second and third transistors and on the second and third gate sidewalls, wherein the first dielectric structure includes a first diameter greater than a second diameter of the second dielectric structure, and the second dielectric structure includes nitrogen in a substantially same composition as the first or second intervening layer.

In one or more tenth embodiments, further to the first through ninth embodiments, an integrated circuit (IC) device includes the first and second transistors, and the IC device is coupled to a substrate and a power supply through the substrate.

In one or more eleventh embodiments, an apparatus includes a nonplanar transistor including a gate structure with a gate sidewall, a via including a metallic material and extending between a first metallization structure over the nonplanar transistor and a second metallization structure under the nonplanar transistor, a first dielectric layer around and in contact with the via, and a second dielectric layer in contact with the first dielectric layer and the gate sidewall, wherein a first diameter of the first dielectric layer is greater than a second diameter of the second dielectric layer.

In one or more twelfth embodiments, further to the eleventh embodiments, the first dielectric layer includes silicon and oxygen, and the second dielectric layer includes silicon and nitrogen.

In one or more thirteenth embodiments, further to the eleventh or twelfth embodiments, the first dielectric layer includes a first atomic composition of at least thirty percent silicon, at least thirty percent oxygen, and less than five percent nitrogen, and the second dielectric layer includes a second atomic composition of at least forty percent silicon, at least fifteen percent nitrogen, and less than five percent oxygen.

In one or more fourteenth embodiments, further to the eleventh through thirteenth embodiments, the nonplanar transistor is a first nonplanar transistor, and the gate sidewall is a first gate sidewall, also including a second nonplanar transistor with a second gate sidewall, wherein the via is between the first and second nonplanar transistors, and the second dielectric layer is in contact with the second gate sidewall.

In one or more fifteenth embodiments, further to the eleventh through fourteenth embodiments, an integrated circuit (IC) device includes the nonplanar transistor and the via, and the IC device is coupled to a substrate and a power supply through the substrate.

In one or more sixteenth embodiments, a method includes receiving a substrate including first and second transistors with a shared gate structure over a first channel region of the first transistor and a second channel region of the second transistor, etching an opening through the shared gate structure and between the first and second channel regions, wherein the opening separates the shared gate structure into first and second gate structures, depositing a conformal layer over a surface of the opening, and filling the opening with an insulator material over the conformal layer.

In one or more seventeenth embodiments, further to the sixteenth embodiments, the method also includes forming a via through the insulator material, wherein the via includes a metallic material.

In one or more eighteenth embodiments, further to the sixteenth or seventeenth embodiments, the method also includes coupling the via to first and second metallization structures, wherein the first metallization structure is over the first and second gate structures, and the first and second gate structures are over the second metallization structure.

In one or more nineteenth embodiments, further to the sixteenth through eighteenth embodiments, the filling the opening includes growing the insulator material to a first thickness greater than twice a second thickness of the conformal layer, and the insulator material includes silicon and oxygen.

In one or more twentieth embodiments, further to the sixteenth through nineteenth embodiments, the depositing the conformal layer includes an atomic layer deposition of at least silicon and nitrogen to a second thickness of less than 4 nm.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a first transistor comprising a first gate structure over one or more first nanoribbons, the first gate structure comprising a first gate sidewall;
a second transistor adjacent the first transistor and comprising a second gate structure over one or more second nanoribbons, the second gate structure comprising a second gate sidewall;
a dielectric structure between the first and second transistors; and
first and second intervening layers, wherein the first intervening layer is on the first gate sidewall, the second intervening layer is on the second gate sidewall, and the dielectric structure is between the first and second intervening layers.

2. The apparatus of claim 1, further comprising a via in contact with the dielectric structure and between the first and second intervening layers, wherein the via comprises a metallic material, and the first or second intervening layer is between the via and the first or second gate structure.

3. The apparatus of claim 2, wherein a first metallization structure is over and in contact with the first or second gate structure, and the via extends between the first and second gate structures and contacts a second metallization structure under the first or second gate structure.

4. The apparatus of claim 2, wherein:
a first thickness of the dielectric structure is between the via and the first or second intervening layer;
a diameter of the via is less than twice the first thickness of the dielectric structure; and
the first thickness is greater than twice a second thickness of the first or second intervening layer.

5. The apparatus of claim 2, wherein:
the dielectric structure comprises a first thickness of less than 10 nm between the via and the first intervening layer, and the first thickness of less than 10 nm between the via and the second intervening layer;
the first intervening layer comprises a second thickness of less than 4 nm between the first gate structure and the dielectric structure;
the second intervening layer comprises the second thickness of less than 4 nm between the second gate structure and the dielectric structure; and
the via has a diameter of less than 20 nm.

6. The apparatus of claim 1, wherein:
the first and second intervening layers comprise a substantially same composition, comprising silicon and nitrogen; and
the dielectric structure comprises silicon and oxygen.

7. The apparatus of claim 6, wherein:
the first and second intervening layers comprise a first atomic composition of at least forty percent silicon, at least fifteen percent nitrogen, and less than five percent oxygen; and
the dielectric structure comprises a second atomic composition of at least thirty percent silicon, at least thirty percent oxygen, and less than five percent nitrogen.

8. The apparatus of claim 1, wherein the first and second intervening layers form a continuous layer on both the first and second gate structures.

9. The apparatus of claim 1, wherein the dielectric structure is a first dielectric structure, and further comprising:
a third transistor comprising a third gate structure over one or more third nanoribbons, the third gate structure comprising a third gate sidewall; and
a second dielectric structure between the second and third transistors and on the second and third gate sidewalls, wherein:
the first dielectric structure comprises a first diameter greater than a second diameter of the second dielectric structure; and
the second dielectric structure comprises nitrogen in a substantially same composition as the first or second intervening layer.

10. The apparatus of claim 1, wherein an integrated circuit (IC) device comprises the first and second transistors, and the IC device is coupled to a substrate and a power supply through the substrate.

11. An apparatus, comprising:
a nonplanar transistor comprising a gate structure with a gate sidewall;
a via comprising a metallic material and extending between a first metallization structure over the nonplanar transistor and a second metallization structure under the nonplanar transistor;
a first dielectric layer around and in contact with the via; and
a second dielectric layer in contact with the first dielectric layer and the gate sidewall, wherein a first diameter of the first dielectric layer is greater than a second diameter of the second dielectric layer.

12. The apparatus of claim 11, wherein the first dielectric layer comprises silicon and oxygen, and the second dielectric layer comprises silicon and nitrogen.

13. The apparatus of claim 12, wherein:
the first dielectric layer comprises a first atomic composition of at least thirty percent silicon, at least thirty percent oxygen, and less than five percent nitrogen; and
the second dielectric layer comprises a second atomic composition of at least forty percent silicon, at least fifteen percent nitrogen, and less than five percent oxygen.

14. The apparatus of claim 13, wherein the nonplanar transistor is a first nonplanar transistor, and the gate sidewall is a first gate sidewall, further comprising a second nonplanar transistor with a second gate sidewall, wherein the via is between the first and second nonplanar transistors, and the second dielectric layer is in contact with the second gate sidewall.

15. The apparatus of claim 14, wherein an integrated circuit (IC) device comprises the nonplanar transistor and the via, and the IC device is coupled to a substrate and a power supply through the substrate.

16. A method, comprising:
receiving a substrate comprising first and second transistors with a shared gate structure over a first channel region of the first transistor and a second channel region of the second transistor;
etching an opening through the shared gate structure and between the first and second channel regions, wherein the opening separates the shared gate structure into first and second gate structures;
depositing a conformal layer over a surface of the opening; and
filling the opening with an insulator material over the conformal layer.

17. The method of claim 16, further comprising forming a via through the insulator material, wherein the via comprises a metallic material.

18. The method of claim 17, further comprising coupling the via to first and second metallization structures, wherein the first metallization structure is over the first and second gate structures, and the first and second gate structures are over the second metallization structure.

19. The method of claim 16, wherein the filling the opening comprises growing the insulator material to a first thickness greater than twice a second thickness of the conformal layer, and the insulator material comprises silicon and oxygen.

20. The method of claim 16, wherein the depositing the conformal layer comprises an atomic layer deposition of at least silicon and nitrogen to a second thickness of less than 4 nm.
